(19) United States
(12) Patent Application Publication
(10) Pub. No.: US 2026/0231751 A1
(43) Pub. Date: Aug. 6, 2026

(54) SEMICONDUCTOR STRUCTURE

(71) Applicant: Taiwan Semiconductor Manufacturing Company, Ltd., Hsinchu (TW)

(72) Inventors: Wan-Jiun Liao, Taichung City (TW); Hui-Wen LI, Hsinchu (TW); Ze-Xian Lu, Hsinchu (TW); Chia-En Huang, Hsinchu County (TW); Jung-Hsuan Chen, Hsinchu City (TW); Ting-Wei Chiang, New Taipei City (TW)

(73) Assignee: Taiwan Semiconductor Manufacturing Company, Ltd., Hsinchu (TW)

(21) Appl. No.: 19/045,561

(22) Filed: Feb. 5, 2025

(51) Int. Cl. H01L 23/522; H01L 23/528; H10D 30/00; H10D 30/43; H10D 62/10; H10D 62/13; H10D 64/01; H10D 64/23; H10D 84/83

(52) U.S. Cl. CPC H10W 20/42; H10D 64/017; H10D 64/258; H10W 20/43; H10W 20/435; H10D 30/43; H10D 30/502; H10D 62/121; H10D 62/151; H10D 84/832

(57) ABSTRACT

A semiconductor structure includes a substrate, dummy gate replacement patterns, source/drain contacts, first conductive vias, at least one first conductive line, second conductive vias, at least one second conductive line, third conductive vias and at least one third conductive line. The dummy gate replacement patterns and the source/drain contacts are disposed on the substrate. The source/drain contacts include first and second contacts. The first conductive vias electrically connect the first contacts to the at least one first conductive line. The second conductive vias electrically connect the second contacts to the at least one second conductive line. The third conductive vias are in the substrate. The at least one third conductive line is disposed below the substrate and electrically connected to the third conductive vias. In a top view, the number of dummy gate replacement patterns between two adjacent third conductive vias is one.

### BACKGROUND

Backside routing is a crucial knob in enhancing PPA (Performance, Power, Area) in advanced nodes. By implementing a denser routing structure, chip scaling can become more competitive. However, backside routing is susceptible to yield loss due to backside vias.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1, FIG. 7, FIG. 10, FIG. 13, FIG. 19, FIG. 22, FIG. 25, FIG. 28, FIG. 31, and FIG. 34 are schematic top views of semiconductor structures according to some embodiments of the present disclosure.

FIG. 2 to FIG. 6 are cross-sectional views corresponding to section lines I-I′, II-II′, III-III′, IV-IV′ and V-V′ in FIG. 1.

FIG. 8 and FIG. 9 are cross-sectional views corresponding to section lines I-I′ and II-II′ in FIG. 7.

FIG. 11 and FIG. 12 are cross-sectional views corresponding to section lines I-I′ and II-II′ in FIG. 10.

FIG. 14 to FIG. 18 are cross-sectional views corresponding to section lines I-I′, II-II′, III-III′, IV-IV′ and V-V′ in FIG. 13.

FIG. 20 and FIG. 21 are cross-sectional views corresponding to section lines I-I′ and II-II′ in FIG. 19.

FIG. 23 and FIG. 24 are cross-sectional views corresponding to section lines I-I′ and II-II′ in FIG. 22.

FIG. 26 and FIG. 27 are cross-sectional views corresponding to section lines I-I′ and II-II′ in FIG. 25.

FIG. 29 and FIG. 30 are cross-sectional views corresponding to section lines I-I′ and II-II′ in FIG. 28.

FIG. 32 and FIG. 33 are cross-sectional views corresponding to section lines I-I′ and II-II′ in FIG. 31.

FIG. 35 to FIG. 38 are cross-sectional views corresponding to section lines I-I′, II-II′, III-III′ and VI-VI′ in FIG. 34.

FIG. 39 is a schematic top view of a frontside metal layer of a semiconductor structure according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Backside routing is electrically connected to components (for example, source/drain regions or source/drain region contacts) disposed on frontside surface of a substrate through conductive vias (hereinafter referred to as “backside conductive vias”) within the substrate. Therefore, the yield of semiconductor structures adopting backside routing is closely related to the yield of the backside conductive vias. When the yield of the backside conductive vias is not ideal, the yield of semiconductor structures adopting backside routing becomes a challenge.

In the present disclosure, novel backside conductive via layouts are provided to increase the number of backside conductive vias that successfully electrically connect the components (for example, source/drain regions or source/drain region contacts) disposed on frontside of the substrate to the backside routing (e.g., the third conductive line), and thus increasing the yield of semiconductor structures adopting backside routing. The novel backside conductive via layout provides flexible placement of the backside conductive vias that can be customized based on process learning or different design requirement, and the novel backside conductive via layout helps enhance header driving current and provide better IR results (e.g., provide a more stable driving voltage) for the semiconductor structures. In addition, the novel backside conductive via layout is compatible with existing manufacturing processes, and additional processes and/or photomasks may be omitted.

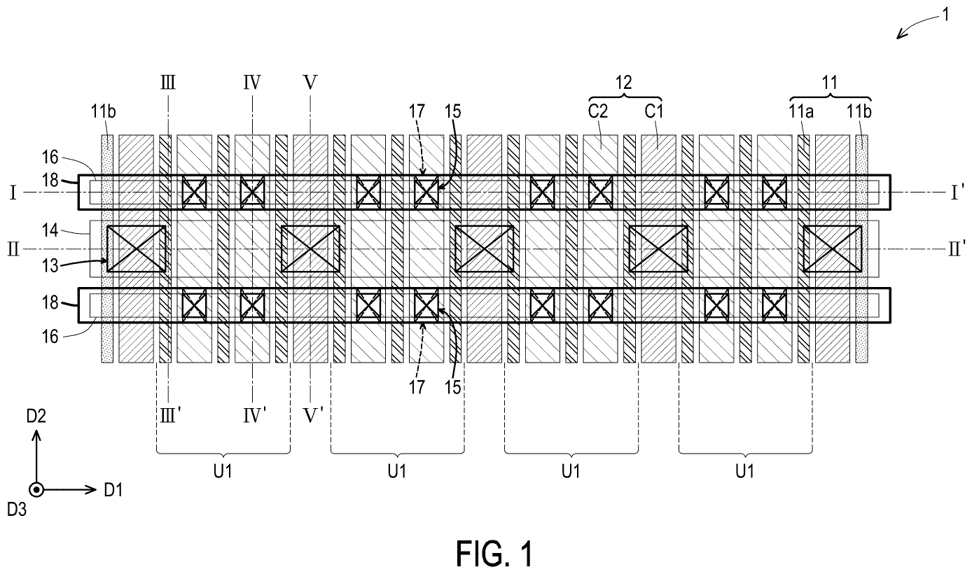

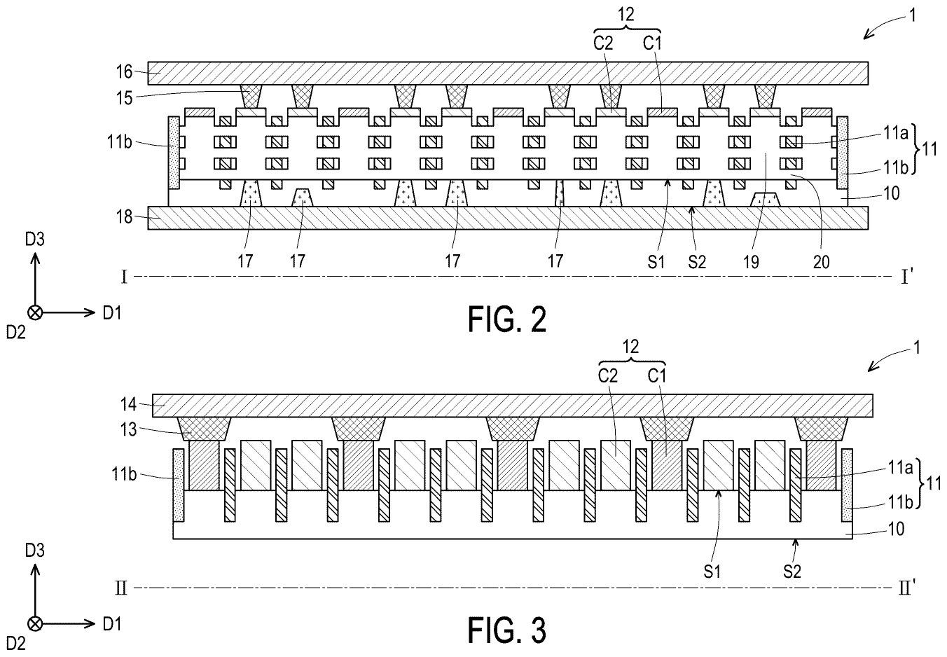

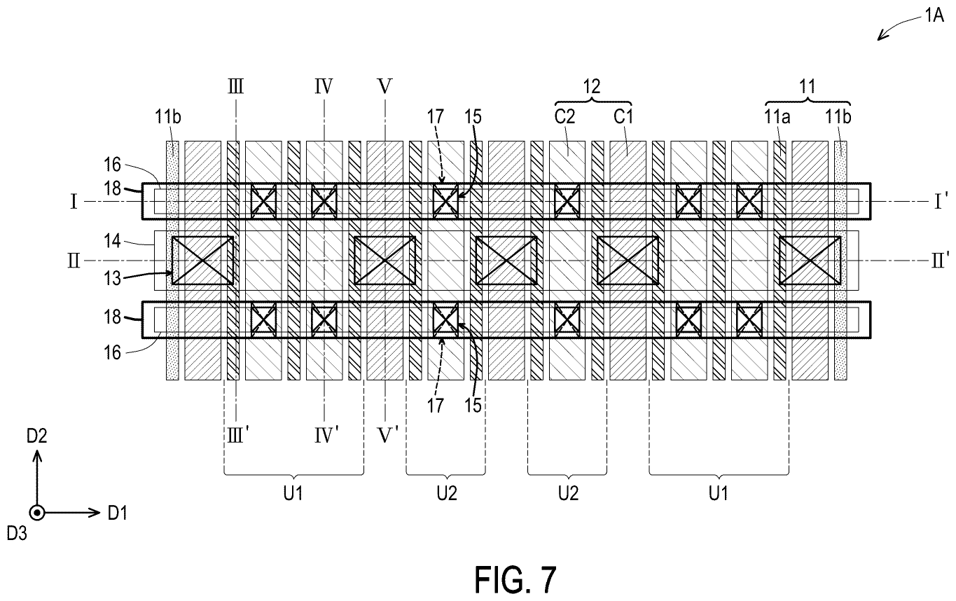

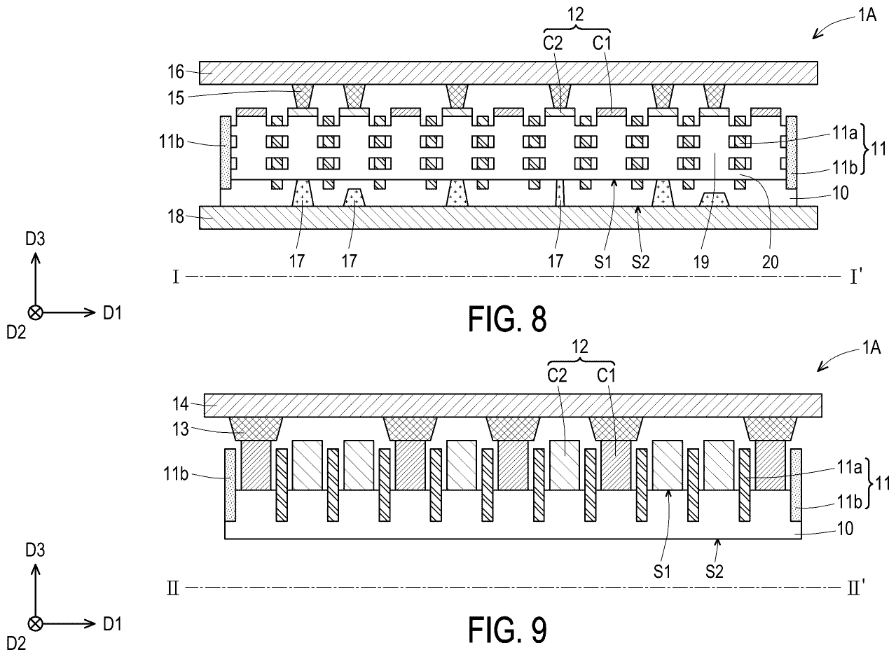

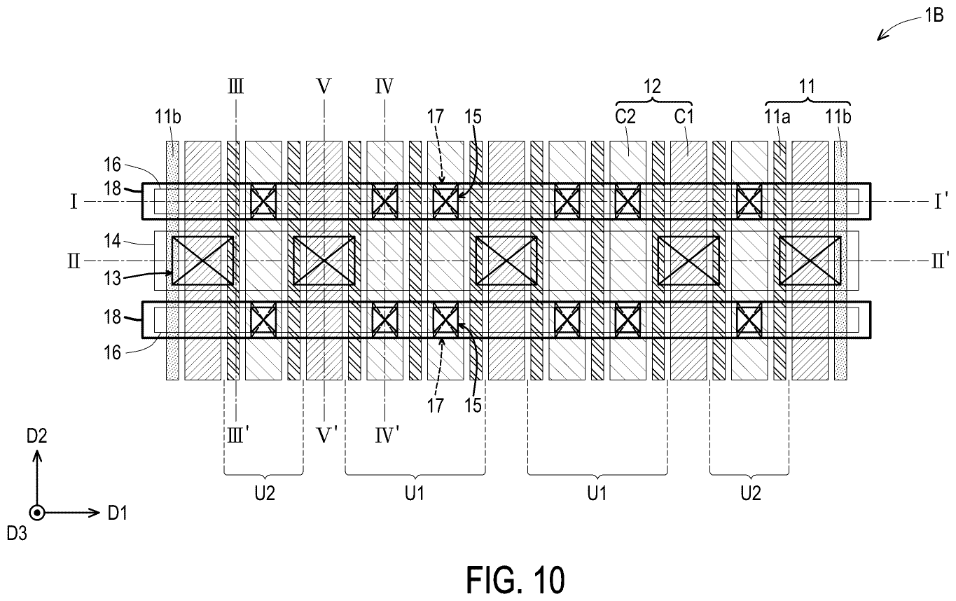

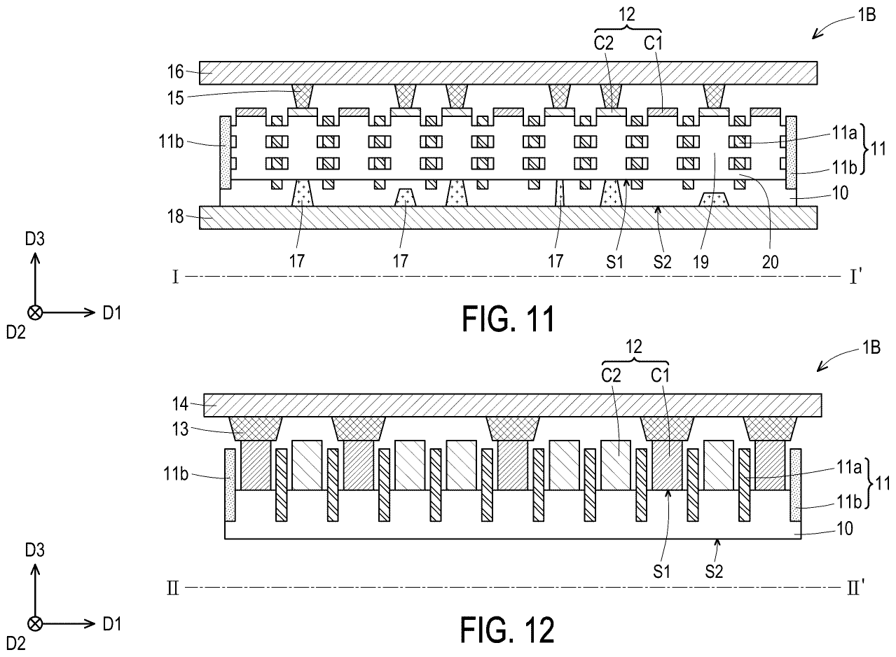

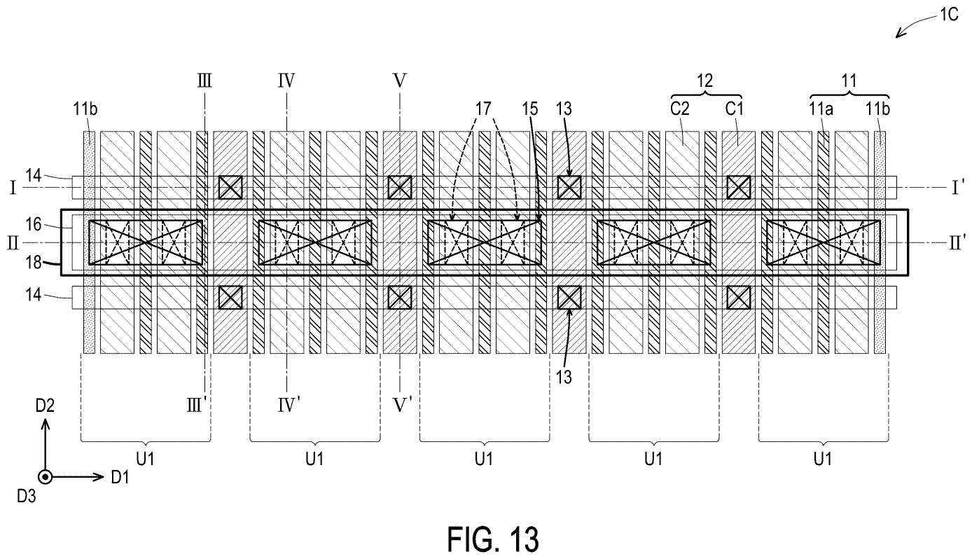

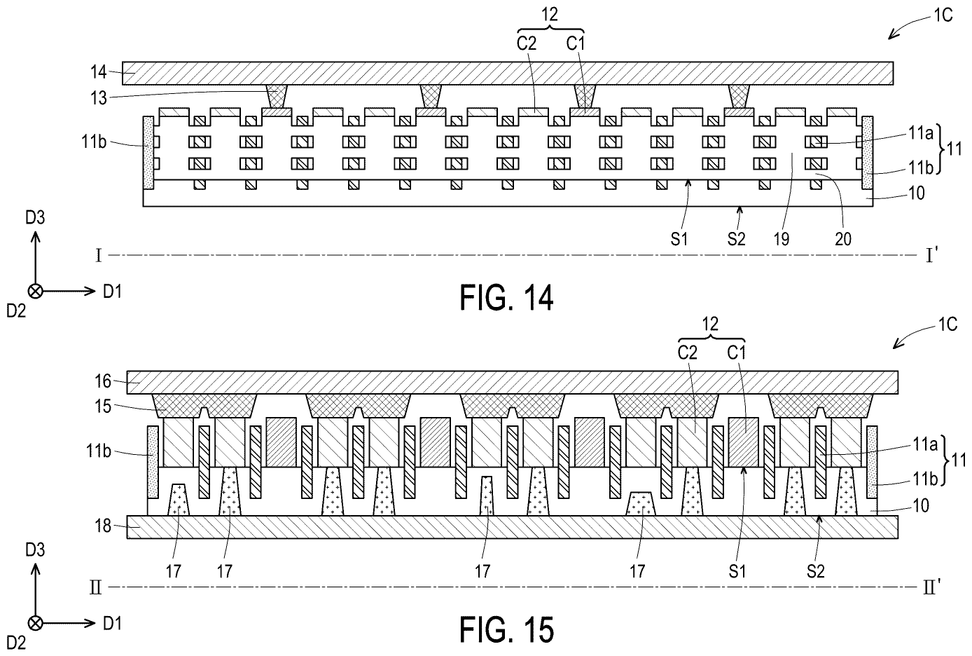

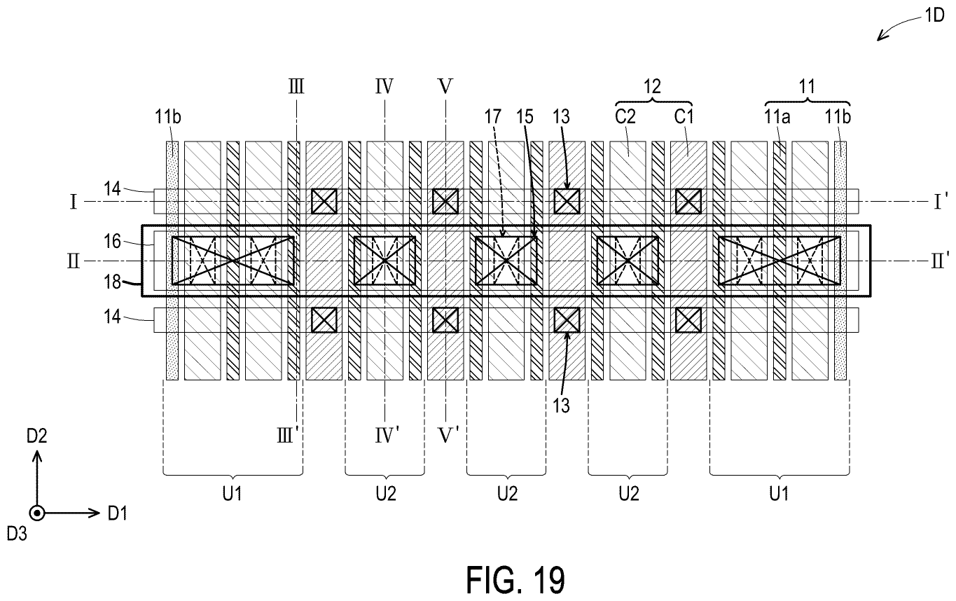

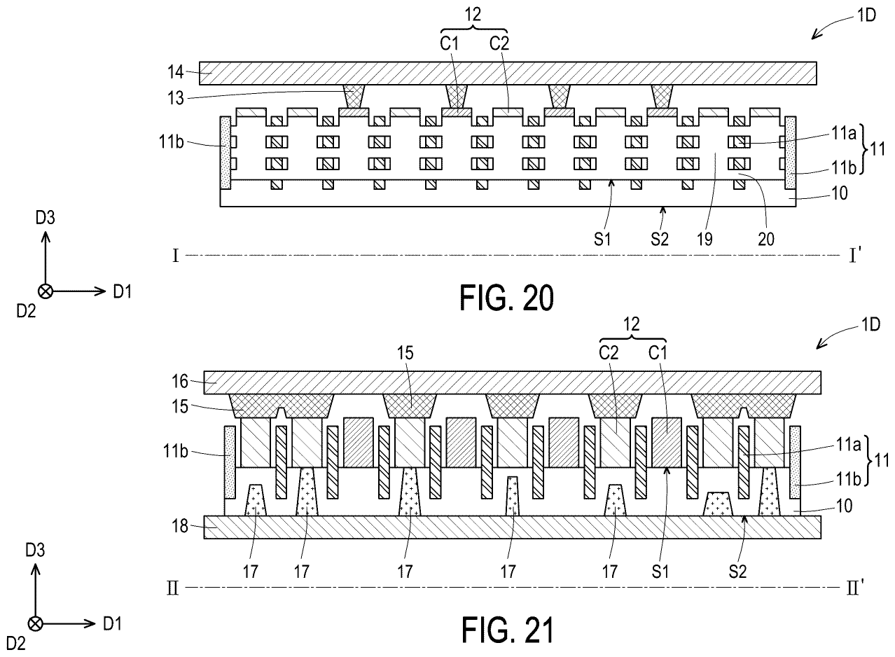

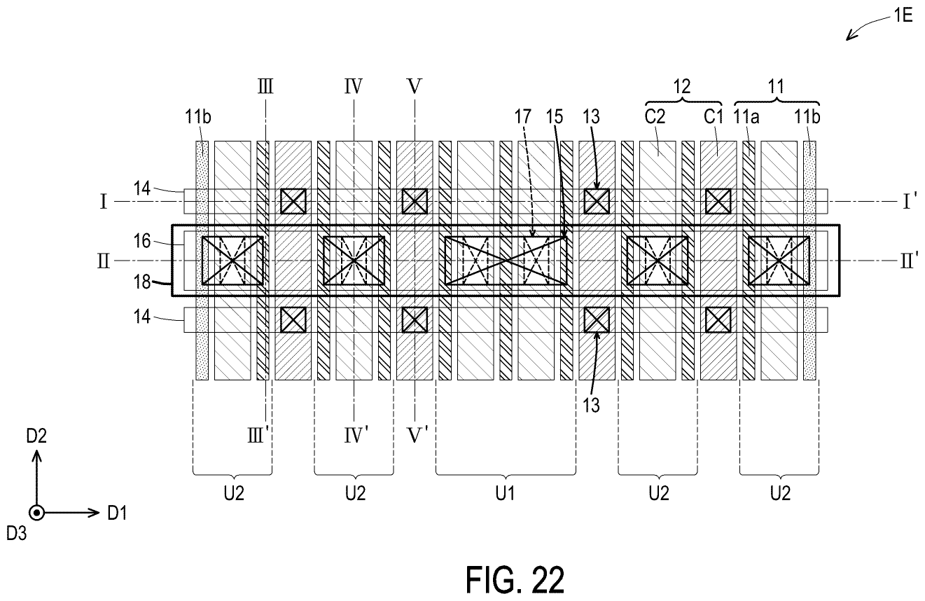

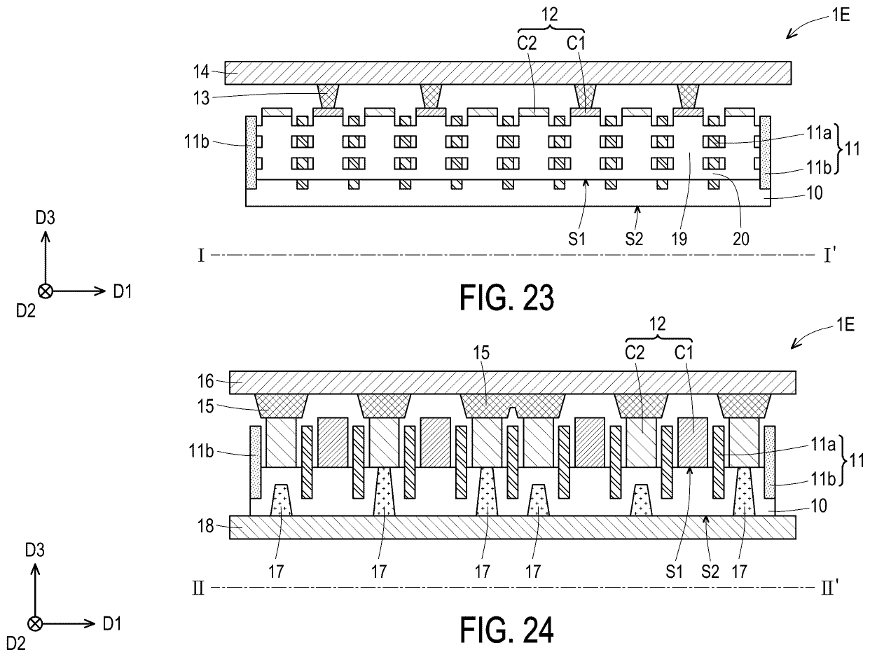

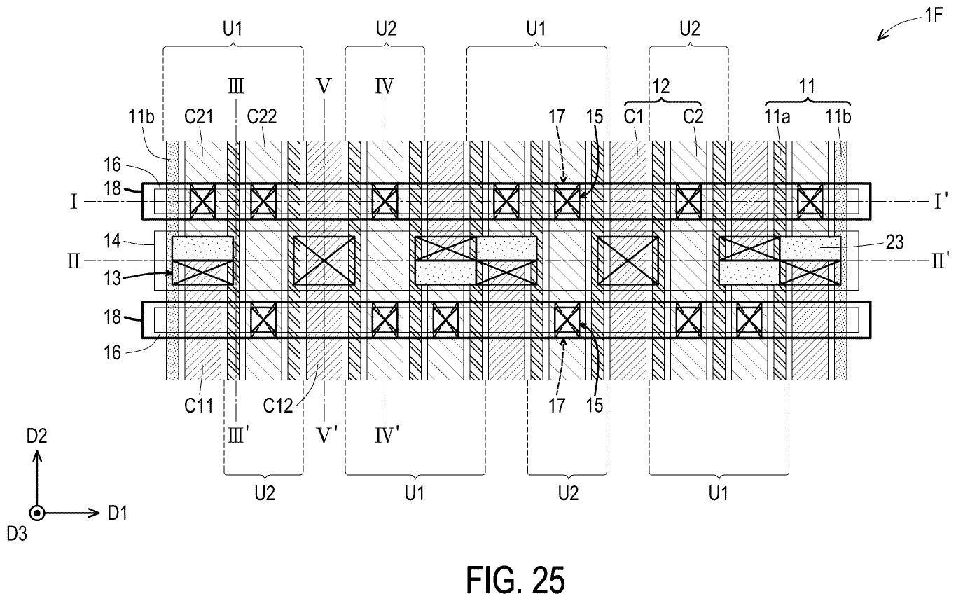

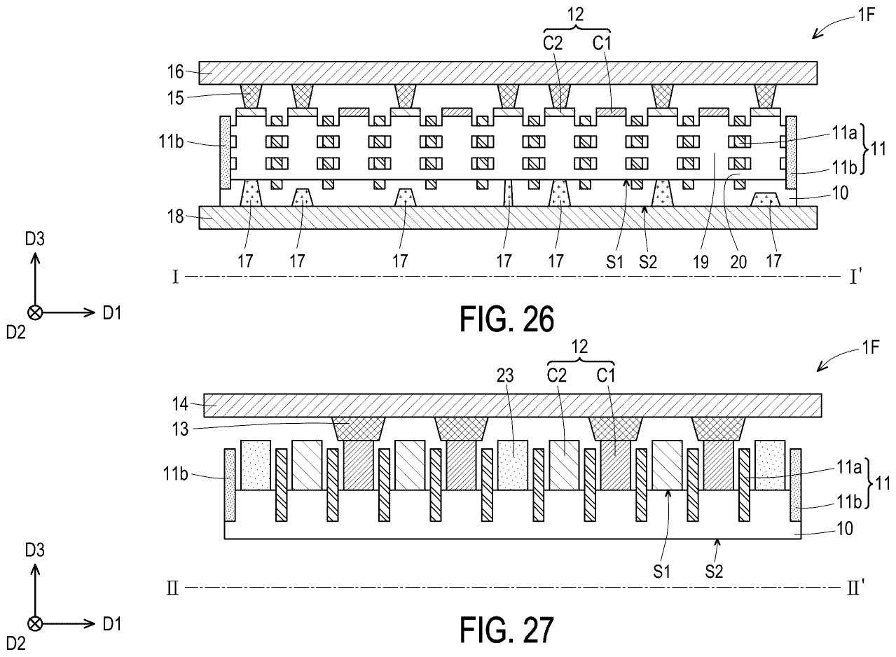

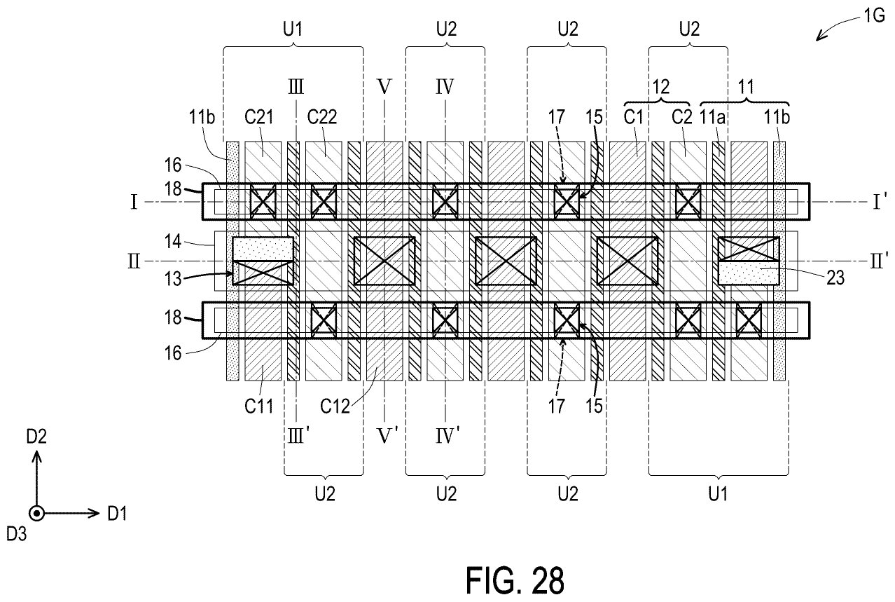

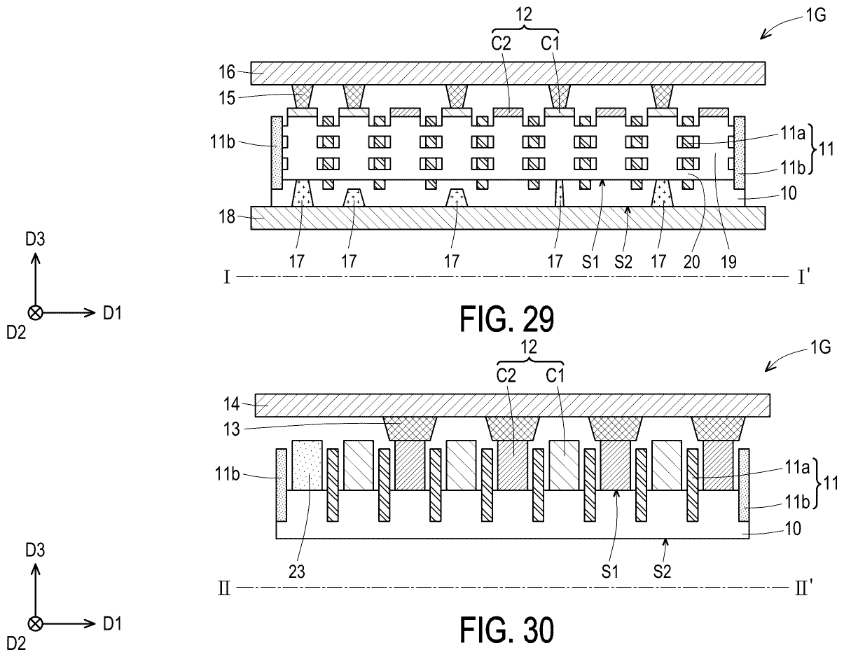

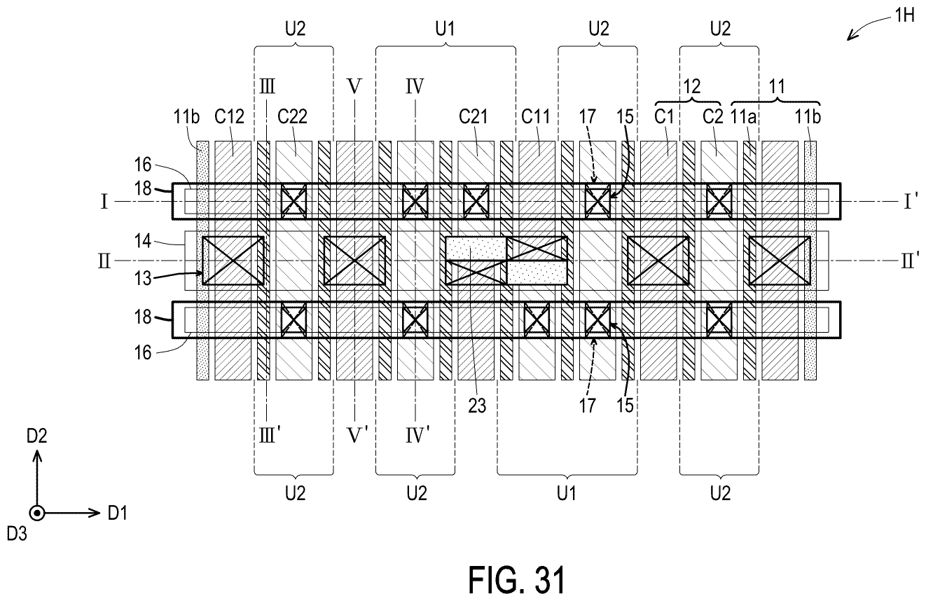

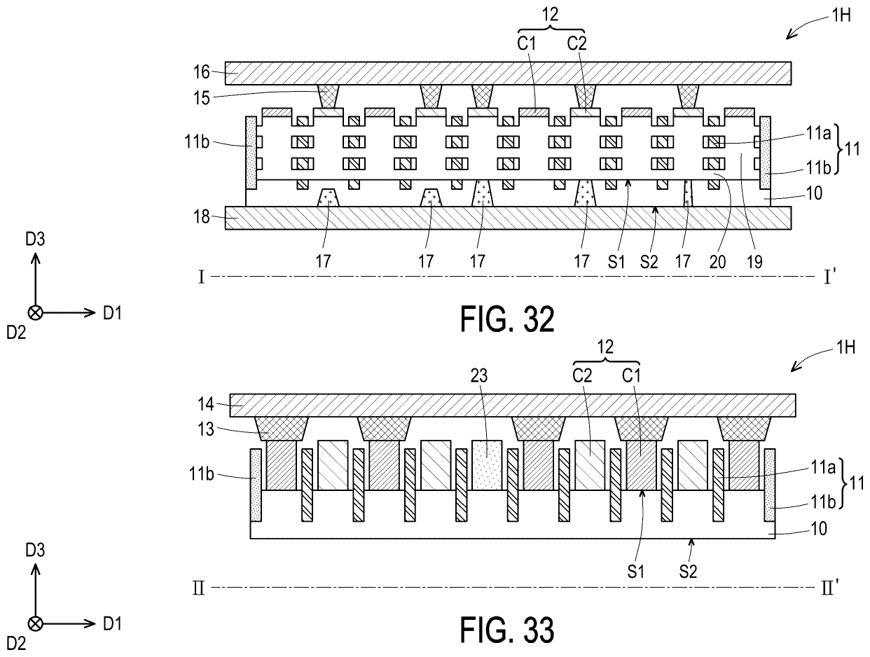

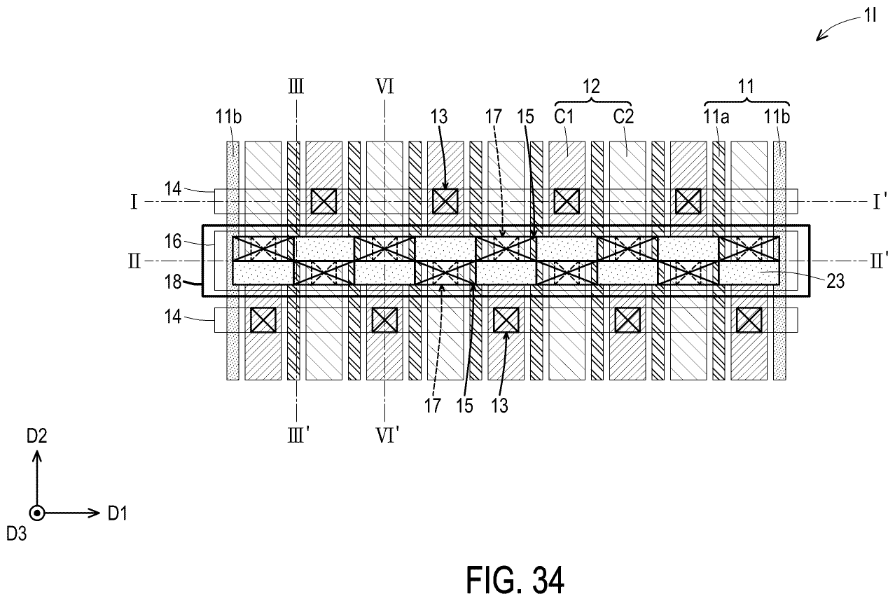

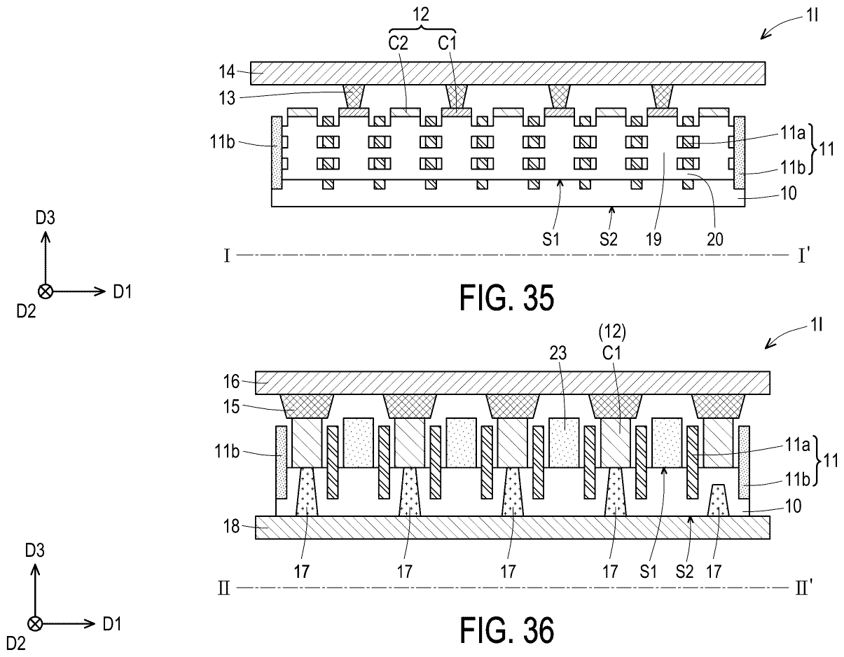

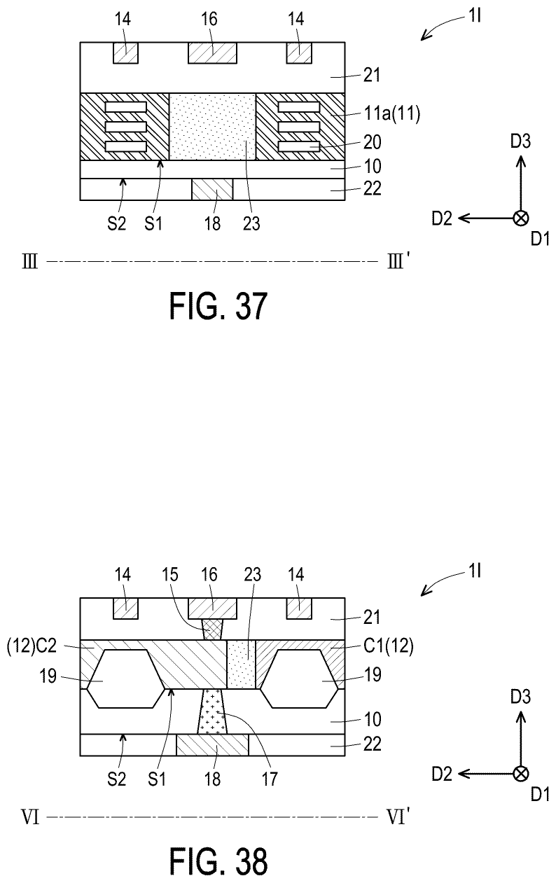

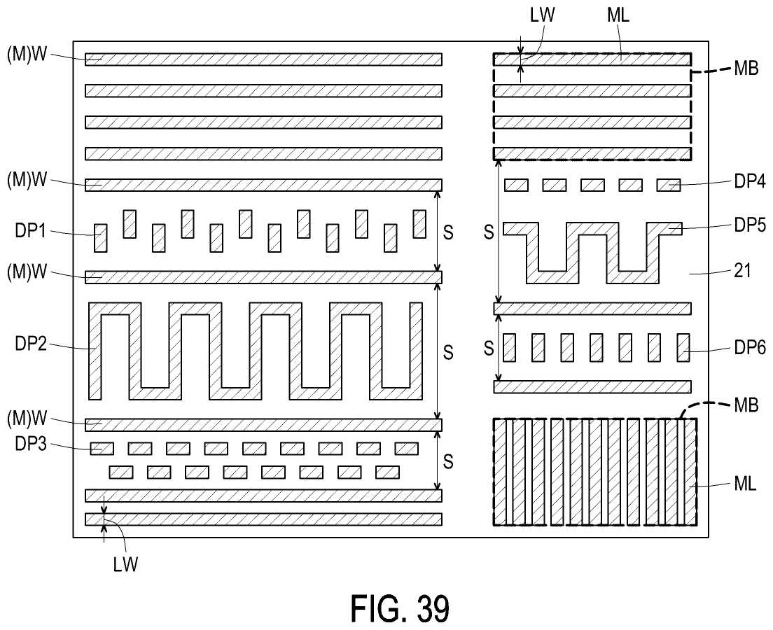

FIG. 1, FIG. 7, FIG. 10, FIG. 13, FIG. 19, FIG. 22, FIG. 25, FIG. 28, FIG. 31, and FIG. 34 are schematic top views of semiconductor structures according to some embodiments of the present disclosure. FIG. 2 to FIG. 6 are cross-sectional views corresponding to section lines I-I′, II-II′, III-III′, IV-IV′ and V-V′ in FIG. 1. FIG. 8 and FIG. 9 are cross-sectional views corresponding to section lines I-I′ and II-II′ in FIG. 7. FIG. 11 and FIG. 12 are cross-sectional views corresponding to section lines I-I′ and II-II′ in FIG. 10. FIG. 14 to FIG. 18 are cross-sectional views corresponding to section lines I-I′, II-II′, III-III′, IV-IV′ and V-V′ in FIG. 13. FIG. 20 and FIG. 21 are cross-sectional views corresponding to section lines I-I′ and II-II′ in FIG. 19. FIG. 23 and FIG. 24 are cross-sectional views corresponding to section lines I-I′ and II-II′ in FIG. 22. FIG. 26 and FIG. 27 are cross-sectional views corresponding to section lines I-I′ and II-II′ in FIG. 25. FIG. 29 and FIG. 30 are cross-sectional views corresponding to section lines I-I′ and II-II′ in FIG. 28. FIG. 32 and FIG. 33 are cross-sectional views corresponding to section lines I-I′ and II-II′ in FIG. 31. FIG. 35 to FIG. 38 are cross-sectional views corresponding to section lines I-I′, II-II′, III-III′ and VI-VI′ in FIG. 34. FIG. 39 is a schematic top view of a frontside metal layer of a semiconductor structure according to some embodiments of the present disclosure. In the top views, some layers or components are not illustrated for simplicity of the drawings. Similarly, in the cross-sectional views corresponding to section lines I-I′ and II-II′, some layers or components are not illustrated for simplicity of the drawings. It should be noted that the drawings only illustrate specific examples for convenience of explanation, but are not intended to limit the present disclosure. For example, design parameters such as the number of components and relative arrangement relationships can be changed according to needs and are not limited to those shown in the drawings.

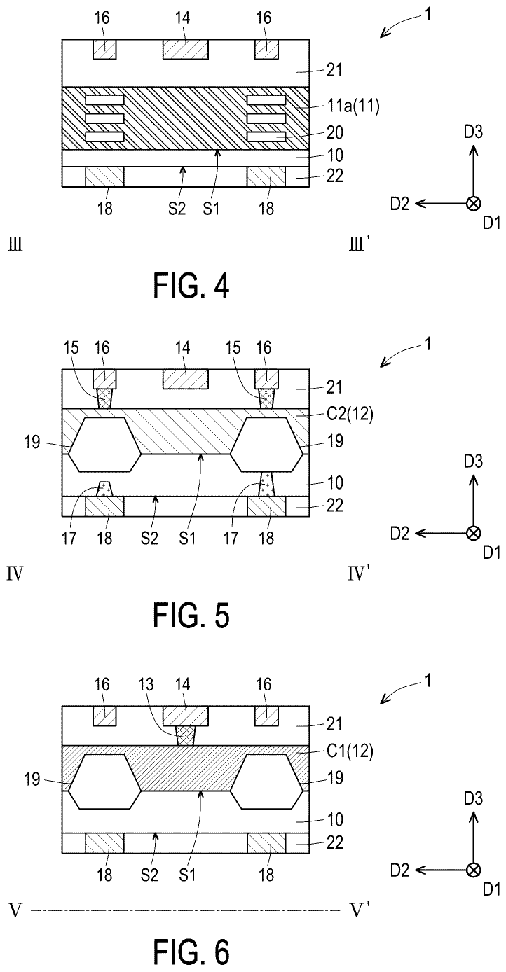

Referring to FIG. 1 to FIG. 6, a semiconductor structure (e.g., a memory structure) 1 according to some embodiments of the present disclosure is provided. The semiconductor structure 1 includes, for example, a substrate 10, a plurality of dummy gate replacement patterns 11, a plurality of source/drain contacts 12, a plurality of first conductive vias 13, at least one first conductive line 14, a plurality of second conductive vias 15, at least one second conductive line 16, a plurality of third conductive vias 17 and at least one third conductive line 18, but not limited thereto. One or more layers or components may be included in the semiconductor structure 1 according to different needs. For example, as shown in FIG. 2 and FIG. 3, the semiconductor structure 1 may further include a plurality of source/drain regions 19 and a plurality of nanosheets 20. In addition, as shown in FIG. 4 to FIG. 6, the semiconductor structure 1 may further include a dielectric layer 21 and a dielectric layer 22.

The substrate 10 includes an element semiconductor such as silicon or germanium, a compound semiconductor such as silicon carbide, gallium arsenic, gallium phosphide, indium phosphide, indium arsenide and indium antimonide, an alloy semiconductor such as SiGe, GaAsP, AlInAs, AlGaAs, GaInAs, GaInP and GaInAsP or a combination thereof.

The substrate 10 has a first surface S1 and a second surface S2 opposite to the first surface S1. In some embodiments, the first surface S1 is a frontside surface or an active surface, while the second surface S2 is a backside surface or a non-active surface.

The plurality of dummy gate replacement patterns 11 is disposed on the first surface S1. As shown in FIG. 1, the plurality of dummy gate replacement patterns 11 may be arranged along a first direction D1 and extend along a second direction D2 intersected with the first direction D1. In some embodiments, as shown in FIG. 1, the second direction D2 is perpendicular to the first direction D1, but not limited thereto.

The plurality of dummy gate replacement patterns 11 is a plurality of patterns that are replaced from a plurality of dummy gate (e.g., made of polysilicon) patterns. For example, as shown in FIG. 1 to FIG. 3, the plurality of dummy gate replacement patterns 11 includes a plurality of metal gate patterns 11a. In some embodiments, although not shown, the metal gate pattern 11a includes a work function metal layer and a metal filling layer. The work function metal layer includes one or more of TaN, TaAlC, TiN, TiC, Co, TiAl, HfTi, TiSi and TaSi. The metal filling layer includes Al, W, Cu or the like.

In some embodiments, although not shown, a gate dielectric layer is formed between each nanosheet 20 and the metal gate pattern 11a. For example, each nanosheet 20 in FIG. 4 may be wrapped by a corresponding gate dielectric layer. The gate dielectric layer includes a high-k material. Examples of the high-k material include metal oxide, such as HfO2, HfSiO, HfSiON, HfTaO, HfTiO, HfZrO, zirconium oxide, aluminum oxide, titanium oxide, hafnium dioxide-alumina (HfO₂—Al₂O₃) alloy, the like, or a combination thereof.

In some embodiments, although not shown, spacers may be disposed on sidewalls of the metal gate pattern 11a. Each of the spacers may have a single-layer or multi-layer structure. In some embodiments, the spacers include a dielectric material, such as silicon oxide, silicon nitride, SiON, SiC, SiCN, SiCON, or a combination thereof. Other materials such as a low-k material may be applicable. The spacers are referred to as “inner spacers” or “sidewall spacers” in some examples.

In some embodiments, although not shown, cap layers are formed over the metal gate patterns 11a. The cap layers may include dielectric caps. The cap layers include silicon oxide, silicon nitride, SiON, SiC, SiCN, SiCON, metal oxide (e.g., Al₂O₃) or a combination thereof.

In some embodiments, as shown in FIG. 1 to FIG. 3, the plurality of dummy gate replacement patterns 11 may further include a plurality of dielectric patterns 11b. The plurality of dielectric patterns 11b (e.g., two dielectric patterns 11b) may be located on opposite sides of the plurality of metal gate patterns 11a. In some embodiments, the dielectric pattern 11b includes silicon oxide, silicon nitride, silicon oxynitride, or a combination thereof. In some alternative embodiments, the dielectric pattern 11b is made of a high-k material.

The plurality of source/drain regions 19 and the plurality of nanosheets 20 are disposed on the first surface S1. As shown in FIG. 2, the plurality of dummy gate replacement patterns 11 and the plurality of nanosheets 20 may be alternately arranged along the first direction D1. The number of nanosheets 20 between two corresponding source/drain regions 19 adjacently disposed along the first direction D1 may be more than one, and the nanosheets 20 between two corresponding source/drain regions 19 adjacently disposed along the first direction D1 may be disposed along a third direction D3 perpendicular to the first direction D1 and the second direction D2.

The source/drain regions 19 may be referred to as “epitaxial layers”, “strained layers” or “highly doped low resistance materials” in some examples. Source/drain region(s) may refer to a source or a drain, individually or collectively dependent upon the context. The source/drain regions 19 are abutted and electrically connected to the nanosheets 20, while the source/drain regions 19 are electrically isolated from the metal gate patterns 11a by the inner spacers (not shown). From another point of view, the nanosheets 20 are suspended between the source/drain regions 19. In some embodiments, the source/drain regions 19 may include silicon, SiC, SiCP, SiP, or the like, and the nanosheets 20 may include silicon or the like.

In some embodiments, although not shown, silicide layers are optionally formed over the source/drain regions 19, respectively. The silicide layers may include tungsten silicide, cobalt silicide, titanium silicide, nickel silicide, the like or a combination thereof.

The plurality of source/drain contacts 12 is disposed on the first surface S1, wherein the plurality of dummy gate replacement patterns 11 and the plurality of source/drain contacts 12 are alternately arranged along the first direction D1, and the plurality of source/drain contacts 12 include a plurality of first contacts C1 and a plurality of second contacts C2 separated from the plurality of first contacts C1.

In some embodiments, as shown in FIG. 1, the plurality of first contacts C1 and the plurality of second contacts C2 extend along the second direction D2, and as shown in FIG. 2 and FIG. 3, the plurality of first contacts C1 and the plurality of second contacts C2 may be disposed on and electrically connected to the plurality of source/drain regions 19. The plurality of first contacts C1 and the plurality of second contacts C2 include Cu, Al, Ti, Ta, W, Ru, Co, Ni, the like, or a combination thereof.

The plurality of first conductive vias 13 is disposed on and electrically connected to the plurality of first contacts C1. The plurality of first conductive vias 13 includes Cu, Al, Ti, Ta, W, Ru, Co, Ni, the like, or a combination thereof.

The at least one first conductive line 14 is disposed on the plurality of first conductive vias 13, wherein the plurality of first contacts C1 is electrically connected to the at least one first conductive line 14 through the plurality of first conductive vias 13. In some embodiments, as shown in FIG. 1, the semiconductor structure 1 includes one first conductive line 14 extending along the first direction D1. However, in other embodiments, the semiconductor structure includes more than one first conductive lines 14 extending along the first direction D1 and arranged along the second direction D2. The first conductive line 14 may belong to a first metal layer (e.g., the layer closest to the substrate 10) among frontside metal layers (not shown). The frontside metal layers include Cu, Al, Ti, Ta, W, Ru, Co, Ni, the like, or a combination thereof.

The plurality of second conductive vias 15 is disposed on and electrically connected to the plurality of second contacts C2. The plurality of second conductive vias 15 includes Cu, Al, Ti, Ta, W, Ru, Co, Ni, the like, or a combination thereof.

The at least one second conductive line 16 is disposed on the plurality of second conductive vias 15, wherein the plurality of second contacts C2 is electrically connected to the at least one second conductive line 16 through the plurality of second conductive vias 15. In some embodiments, as shown in FIG. 1, the semiconductor structure 1 includes two second conductive lines 16 extending along the first direction D1 and arranged along the second direction D2, wherein the first conductive line 14 is located between the two second conductive lines 16. However, the semiconductor structure may include more than two second conductive lines 16. Moreover, in the embodiments in which the semiconductor structure includes more than one first conductive lines 14, the semiconductor structure may include one second conductive lines 16 located between the first conductive lines 14. The second conductive lines 16 may also belong to the first metal layer (e.g., the layer closest to the substrate 10) among the frontside metal layers (not shown).

In some embodiments, as shown in FIG. 4 to FIG. 6, the plurality of first conductive vias 13 the at least one first conductive line 14, the plurality of second conductive vias 15 and the at least one second conductive line 16 are embedded in the dielectric layer 21 (or called frontside first dielectric layer). The dielectric layer 21 may include silicon oxide, silicon oxynitride, silicon nitride, a low low-k material having a dielectric constant less than 3.5, the like, or a combination thereof. The dielectric layer 21 is referred to as an “interlayer dielectric (ILD) layer” in some embodiments, and the frontside metal layers may be embedded in the interlayer dielectric layer.

In some embodiments, although not shown, a metal liner layer may be disposed between each contact (e.g., the first contact C1 and the second contact C2) and the dielectric layer 21 and between each conductive via (e.g., the first conductive via 13 and the second conductive via 15) and the dielectric layer 21 and between each conductive line (e.g., the first conductive line 14 and the second conductive line 16) and the dielectric layer 21. In some embodiments, the metal liner layer includes a seed layer and/or a barrier layer. The seed layer may include Ti/Cu. The barrier layer may include Ta, TaN, Ti, TiN, CoW or a combination thereof.

The plurality of third conductive vias 17 (or called backside contacts) is disposed in the substrate 10. In some embodiments, as shown in FIG. 1, the plurality of third conductive vias 17 may at least partially overlap the plurality of second conductive vias 15 to shorten the electrical signal transmission path and/or reduce the component layout area. However, in other embodiments, although not shown, the plurality of third conductive vias 17 may not overlap the plurality of second conductive vias 15. The plurality of third conductive vias 17 includes Cu, Al, Ti, Ta, W, Ru, Co, Ni, the like, or a combination thereof.

The at least one third conductive line 18 is disposed on the second surface S2 and electrically connected to the plurality of third conductive vias 17. In some embodiments, as shown in FIG. 1, the semiconductor structure 1 includes two third conductive lines 18 extending along the first direction D1 and arranged along the second direction D2, wherein the first conductive line 14 is located between the two third conductive lines 18. However, the semiconductor structure may include more than two third conductive lines 18. Moreover, in the embodiments in which the semiconductor structure includes more than one first conductive lines 14, the semiconductor structure may include one third conductive line 18 located between the first conductive lines 14. The third conductive line 18 may belong to the first metal layer (e.g., the layer closest to the substrate 10) among the backside metal layers (not shown).

In some embodiments, as shown in FIG. 4 to FIG. 6, the at least one third conductive line 18 is embedded in the dielectric layer 22 (or called backside first dielectric layer). The dielectric layer 22 may include silicon oxide, silicon oxynitride, silicon nitride, a low low-k material having a dielectric constant less than 3.5, the like, or a combination thereof, and the backside metal layers may be embedded in the dielectric layer 22.

In some embodiments, although not shown, a metal liner layer may be disposed between each conductive line (e.g., the third conductive line 18) and the dielectric layer 22. In some embodiments, the metal liner layer includes a seed layer and/or a barrier layer. The seed layer may include Ti/Cu. The barrier layer may include Ta, TaN, Ti, TiN, CoW or a combination thereof.

As shown in FIG. 2 or FIG. 5, shapes and/or sizes of the third conductive vias 17 may be different due to process variations of the third conductive vias 17. The third conductive vias 17 are configured to electrically connect the at least one third conductive line 18 to the components (e.g., the source/drain regions 19 shown in FIG. 2) disposed on the first surface S1 of the substrate 10. However, due to process variations, some of the third conductive vias 17 are unable to land on or connect the components (e.g., the source/drain regions 19 shown in FIG. 2) disposed on the first surface S1 of the substrate 10 (hereinafter referred to as “backside conductive via failure”), leading to open circuits in some of the backside electrical transmission paths.

In the embodiment, in order to reduce the yield loss due to backside conductive via failure, two second contacts C2 are disposed between two first contacts C1 adjacently disposed along the first direction D1, wherein the two second contacts C2 correspond to two groups of third conductive vias 17 respectively electrically connected to the two third conductive lines 18, and each group includes two third conductive vias 17 adjacently disposed along the first direction D1 and respectively overlapping and electrically connected to the two second contacts C2. In some embodiments, in a top view, as shown in FIG. 1, a number of dummy gate replacement patterns 11 between two adjacent third conductive vias 17 among the plurality of third conductive vias 17 is one. In some embodiments, in a cross-sectional view, as shown in FIG. 2, a number of third conductive vias 17 between two adjacent first contacts C1 arranged in the first direction D1 among the plurality of first contacts C1 is two.

In some embodiments, as shown in FIG. 1, the semiconductor structure 1 includes at least one first unit (also referred to as “backside conductive via enhancement unit”) U1, each of the at least one first unit U1 includes three adjacent dummy gate replacement patterns 11 among the plurality of dummy gate replacement patterns 11 and two adjacent second contacts C2 among the plurality of second contacts C2, and the three adjacent dummy gate replacement patterns 11 and the two adjacent second contacts C2 are alternately arranged along the first direction D1. In some embodiments, as shown in FIG. 1, the at least one first unit U1 includes a plurality of first units U1, and the plurality of first units U1 can be disposed in both of the peripheral region and the central region of the semiconductor structure 1. However, in other embodiments, although not shown in FIG. 1, the at least one first unit U1 can be disposed in one of the peripheral region and the central region of the semiconductor structure. In some embodiments, as shown in FIG. 1, the at least one first unit U1 is disposed between two corresponding first contacts C1 adjacently disposed along the first direction D1 among the plurality of first contacts C1. In some embodiments, as shown in FIG. 1, any two first contacts C1 adjacently disposed along the first direction D1 is inserted with a corresponding first unit U1 to effectively improve the backside conductive via failure issue.

Although the transistor (not labeled) in the semiconductor structure 1 is shown to have a gate all around (GAA) structure (as shown in FIG. 4), the present disclosure is not limited thereto. For example, in other embodiments, the transistor has a FinFET structure or other structure. The following embodiments can also be changed accordingly and will not be repeated below.

Although the third conductive vias 17 are shown to have a rectangular top view shape, the present disclosure is not limited thereto. The shape of the third conductive vias 17 can be changed to improve the etching rate of the third conductive vias 17 so as to improve the contact between the source/drain regions 19 and the third conductive vias 17. For example, in other embodiments, the third conductive vias 17 can have a round top view shape or other top view shape. In some embodiments, although not shown, the contact between the source/drain regions 19 and the third conductive vias 17 can also be improved or ensured by an over-etching effect. The following embodiments can also be changed accordingly and will not be repeated below.

Referring to FIG. 7 to FIG. 9, a semiconductor structure (e.g., a memory structure) 1A according to some embodiments of the present disclosure is provided. The cross-sectional views corresponding to section lines I-I′, II-II′ and III-III′ in FIG. 7 can refer to FIG. 4 to FIG. 6.

In the semiconductor structure 1A, the backside conductive via enhancement design is adopted locally for layout area reduction. For example, the backside conductive via enhancement design is adopted in the peripheral region of the semiconductor structure 1A and not adopted in the central region of the semiconductor structure 1A. As shown in FIG. 7, the first units U1 are disposed in the peripheral region of the semiconductor structure 1A. Moreover, in the top view, as shown in FIG. 7, the semiconductor structure 1A further includes at least one second unit U2 (also referred to as “backside conductive via non-enhancement unit”), each of the at least one second unit U2 includes two adjacent dummy gate replacement patterns 11 among the plurality of dummy gate replacement patterns 11 and one second contact C2 among the plurality of second contacts C2, and the second contact C2 is disposed between the two adjacent dummy gate replacement patterns 11. In some embodiments, in the top view, as shown in FIG. 7, one of the plurality of first contacts C1 is disposed between the at least one first unit U1 and the at least one second unit U2. In some embodiments, in the cross-sectional view, as shown in FIG. 8, a number of third conductive vias between two adjacent first contacts C1 arranged in the first direction D1 among the plurality of first contacts C1 is two, while a number of third conductive vias 17 between another two adjacent first contacts C1 arranged in the first direction D1 among the plurality of first contacts C1 is one.

Referring to FIG. 10 to FIG. 12, a semiconductor structure (e.g., a memory structure) 1B according to some embodiments of the present disclosure is provided. The cross-sectional views corresponding to section lines I-I′, II-II′ and III-III′ in FIG. 10 can refer to FIG. 4 to FIG. 6.

In the semiconductor structure 1B, the first units U1 are disposed in the central region of the semiconductor structure 1B, while the second units U2 are disposed in the peripheral region of the semiconductor structure 1B. Namely, the backside conductive via enhancement design is adopted in the central region of the semiconductor structure 1B and not adopted in the peripheral region of the semiconductor structure 1B.

Referring to FIG. 13 to FIG. 18, a semiconductor structure (e.g., a memory structure) 1C according to some embodiments of the present disclosure is provided. In the semiconductor structure 1C, the at least one first conductive line 14 includes two first conductive lines 14 arranged along the second direction D2 parallel to the extension direction of the plurality of dummy gate replacement patterns 11, and in the top view, as shown in FIG. 13, the at least one second conductive line 16 (e.g., one second conductive line 16) and the at least one third conductive line 18 (e.g., one third conductive line 18) are located between the two first conductive lines 14.

In some embodiments, as shown in FIG. 15, one of the plurality of second conductive vias 15 overlaps two of the plurality of third conductive vias 17. For example, each second conductive via 15 overlaps two corresponding third conductive vias 17. Moreover, each second conductive via 15 may be disposed on and electrically connected to two corresponding second contacts C2, but not limited thereto.

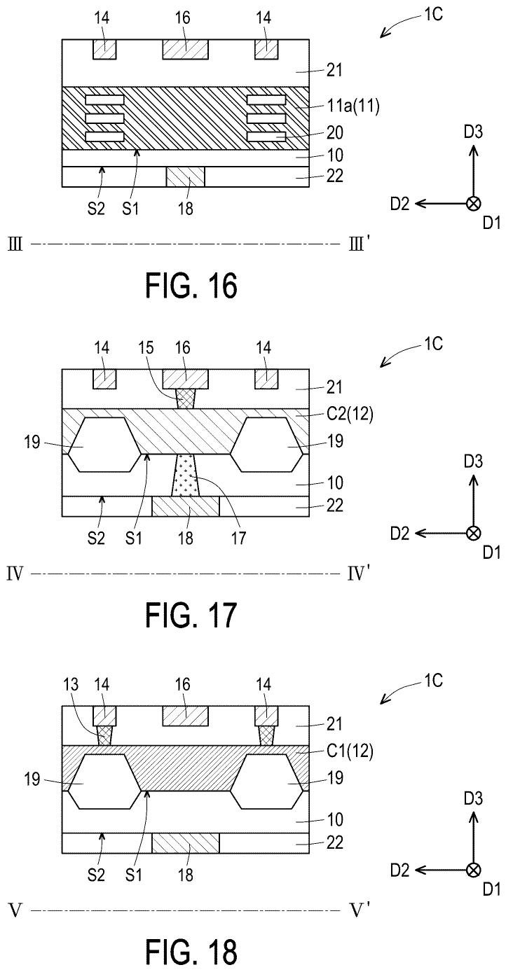

Referring to FIG. 19 to FIG. 21, a semiconductor structure (e.g., a memory structure) 1D according to some embodiments of the present disclosure is provided. The cross-sectional views corresponding to section lines I-I′, II-II′ and III-III′ in FIG. 19 can refer to FIG. 16 to FIG. 18.

In the semiconductor structure 1D, the backside conductive via enhancement design is adopted locally for layout area reduction. For example, the backside conductive via enhancement design is adopted in the peripheral region of the semiconductor structure 1D and not adopted in the central region of the semiconductor structure 1D. As shown in FIG. 19, the first units U1 (e.g., the backside conductive via enhancement units) are disposed in the peripheral region of the semiconductor structure 1D, while the second units U2 (e.g., the backside conductive via non-enhancement units) are disposed in the central region of the semiconductor structure 1D. In some embodiments, as shown in FIG. 21, one of the plurality of second conductive vias 15 overlaps two of the plurality of third conductive vias 17, while another one of the plurality of second conductive vias 15 overlaps one of the plurality of third conductive vias 17. Accordingly, the second conductive via 15 overlapping two third conductive vias 17 may be wider than the second conductive via 15 overlapping one third conductive vias 17 along the first direction D1.

Referring to FIG. 22 to FIG. 24, a semiconductor structure (e.g., a memory structure) 1E according to some embodiments of the present disclosure is provided. The cross-sectional views corresponding to section lines I-I′, II-II′ and III-III′ in FIG. 22 can refer to FIG. 16 to FIG. 18.

In the semiconductor structure 1E, the first units U1 are disposed in the central region of the semiconductor structure 1E, while the second units U2 are disposed in the peripheral region of the semiconductor structure 1E. Namely, the backside conductive via enhancement design is adopted in the central region of the semiconductor structure 1E and not adopted in the peripheral region of the semiconductor structure 1E.

Referring to FIG. 25 to FIG. 27, a semiconductor structure (e.g., a memory structure) 1F according to some embodiments of the present disclosure is provided. The cross-sectional views corresponding to section lines I-I′, II-II′ and III-III′ in FIG. 25 can refer to FIG. 4 to FIG. 6.

In the semiconductor structure 1F, a plurality of second units U2 as well as a plurality of first units U1 are included, wherein the plurality of second units U2 and the plurality of first units U1 are alternately arranged along the first direction D1, and a corresponding first contact C1 (e.g., first contact C11 or first contact C12) is inserted between each second unit U2 and an adjacent first unit U1.

In some embodiments, in the top view, as shown in FIG. 25, one of the plurality of first contacts C1 (e.g., first contact C11) and one of the plurality of second contacts C2 (e.g., second contact C21) are arranged along the second direction D2, wherein the one of the plurality of first contacts C1 (e.g., first contact C11) and the one of the plurality of second contacts C2 (e.g., second contact C21) are separated by a dielectric block 23 disposed adjacent to a first conductive via 13 electrically connected to the one of the plurality of first contacts C1 (e.g., first contact C11). The dielectric block 23 includes silicon oxide, silicon nitride, silicon oxynitride, or a combination thereof. In some alternative embodiments, the dielectric block 23 is made of a high-k material.

In addition, the one of the plurality of first contacts C1 (e.g., first contact C11) may be shorter than another one of the plurality of first contacts C1 (e.g., first contact C12), and the one of the plurality of second contacts C2 (e.g., second contact C21) may be shorter than another one of the plurality of second contacts C2 (e.g., second contact C22). In some embodiments, as shown in FIG. 25, the one of the plurality of first contacts C1 (e.g., first contact C11) may be longer than the one of the plurality of second contacts C2 (e.g., second contact C21).

Specifically, as shown in FIG. 25, the plurality of first contacts C1 includes a plurality of first contacts C11 and a plurality of first contacts C12, wherein the plurality of first contacts C11 are shorter than the plurality of first contacts C12, and the plurality of first contacts C11 and the plurality of first contacts C12 are alternately arranged along the first direction D1. In addition, the plurality of second contacts C2 includes a plurality of second contacts C21 and a plurality of second contacts C22, wherein the plurality of second contacts C21 are shorter than the plurality of second contacts C22, and two corresponding second contacts C22 are disposed between any two second contacts C21 adjacently disposed along the first direction D1. The second contact C22 may be disposed between the first contact C12 and the second contact C21. Moreover, along the second direction D2, the first conductive vias 13 overlapping the first contacts C12 is wider than the first conductive vias 13 overlapping the first contacts C11.

Through the novel backside conductive via layout described above, not only the contact between the source/drain regions 19 and the third conductive vias 17 can be improved, but also the layout area of the semiconductor structure 1F can be reduced.

Referring to FIG. 28 to FIG. 30, a semiconductor structure (e.g., a memory structure) 1G according to some embodiments of the present disclosure is provided. The cross-sectional views corresponding to section lines I-I′, II-II′ and III-III′ in FIG. 28 can refer to FIG. 4 to FIG. 6.

In the semiconductor structure 1G, the backside conductive via enhancement design is adopted in the peripheral region of the semiconductor structure 1G and not adopted in the central region of the semiconductor structure 1G.

Referring to FIG. 31 to FIG. 33, a semiconductor structure (e.g., a memory structure) 1H according to some embodiments of the present disclosure is provided. The cross-sectional views corresponding to section lines I-I′, II-II′ and III-III′ in FIG. 31 can refer to FIG. 4 to FIG. 6.

In the semiconductor structure 1H, the backside conductive via enhancement design is adopted in the central region of the semiconductor structure 1H and not adopted in the peripheral region of the semiconductor structure 1H.

Referring to FIG. 34 to FIG. 38, a semiconductor structure (e.g., a memory structure) 1I according to some embodiments of the present disclosure is provided. In the semiconductor structure 1I, in the top view, as shown in FIG. 34, the plurality of first contacts C1 and the plurality of second contacts C2 are alternately arranged along the first direction D1, one of the plurality of first contacts C1 and one of the plurality of second contacts C2 are arranged along the second direction D2. In addition, the dielectric block 23 is disposed between the first contact C1 and the second contact C2 arranged along the second direction D2. For example, in the top view, as shown in FIG. 34, the dielectric block 23 is disposed between the first contact C1 and the second conductive via 15 (or the third conductive via 17), and the second conductive via 15 (or the third conductive via 17) is disposed between the dielectric block 23 and the second contact C2. In some embodiments, as shown in FIG. 34, the plurality of first contacts C1 may be shorter than the plurality of second contacts C2. In some embodiments, as shown in FIG. 34, the plurality of dielectric blocks 23 and the plurality of second conductive vias 15 (or the plurality of third conductive vias 17) are alternately arranged along the first direction D1. In some embodiments, as shown in FIG. 34, the plurality of first conductive vias 13, the plurality of dielectric blocks 23 and the plurality of second conductive vias 15 (or the plurality of third conductive vias 17) are arranged along the second direction D2.

Through the novel backside conductive via layout described above, not only the contact between the source/drain regions 19 and the third conductive vias 17 can be improved, but also the layout area of the semiconductor structure 1I can be reduced.

Referring to FIG. 39, a frontside metal layer M is provided. The frontside metal layer M may belong to any frontside metal layer (e.g., a metal layer of the back end of line) disposed on the first surface S1 (see FIG. 2) of the substrate 10 (see FIG. 2), and the frontside metal layer M is embedded in the dielectric layer 21 (or called frontside first dielectric layer). The frontside metal layer M is a patterned layer and may include a plurality of metal features, such as a plurality of wirings W, a plurality of conductive vias (not shown) and/or a plurality of dummy patterns (e.g., dummy patterns DP1, a dummy pattern DP2, dummy patterns DP3, dummy patterns DP4, a dummy pattern DP5 and dummy patterns DP6).

The hardness of the substrate may be locally different due to the density of the metal features. When the substrate is flipped over and then thinned to prepare the plurality of third conductive vias 17, the strain effect from the frontside metal density affects the uniformity of substrate thinning, thereby causing a yield loss of in the subsequent formation of the plurality of third conductive vias 17. Accordingly, to counterbalance the strain during the substrate thinning process, dummy patterns may be included to balance the density of the metal features. For example, dummy patterns may be inserted between two adjacent wirings W such that the spacing S between adjacent wirings W is less than 10 times the minimum line width LW of the wirings W. Moreover, large metal blocks MB can be replaced by a plurality of thin metal lines ML such that the maximum line width MLW is less than 50 times the minimum line width LW of the wirings W. Through the above design, ultra-high metal density can be avoided, and thus improving the yield of the plurality of third conductive vias 17.

Based on the above discussions, it can be seen that the present disclosure offers various advantages. It is understood, however, that not all advantages are necessarily discussed herein, and other embodiments may offer different advantages, and that no particular advantage is required for all embodiments.

According to some embodiments, a semiconductor structure includes a substrate, a plurality of dummy gate replacement patterns, a plurality of source/drain contacts, a plurality of first conductive vias, at least one first conductive line, a plurality of second conductive vias, at least one second conductive line, a plurality of third conductive vias and at least one third conductive line. The substrate has a first surface and a second surface opposite to the first surface. The plurality of dummy gate replacement patterns is disposed on the first surface. The plurality of source/drain contacts is disposed on the first surface, wherein the plurality of dummy gate replacement patterns and the plurality of source/drain contacts are alternately arranged along a first direction, and the plurality of source/drain contacts include a plurality of first contacts and a plurality of second contacts separated from the plurality of first contacts. The plurality of first conductive vias is disposed on the plurality of first contacts. The at least one first conductive line is disposed on the plurality of first conductive vias, wherein the plurality of first contacts is electrically connected to the at least one first conductive line through the plurality of first conductive vias. The plurality of second conductive vias is disposed on the plurality of second contacts. The at least one second conductive line is disposed on the plurality of second conductive vias, wherein the plurality of second contacts is electrically connected to the at least one second conductive line through the plurality of second conductive vias. The plurality of third conductive vias is disposed in the substrate. The at least one third conductive line is disposed on the second surface and electrically connected to the plurality of third conductive vias. In a top view, a number of dummy gate replacement patterns between two adjacent third conductive vias among the plurality of third conductive vias is one. In some embodiments, in a cross-sectional view, a number of third conductive vias between two adjacent first contacts arranged in the first direction among the plurality of first contacts is two. In some embodiments, in the cross-sectional view, a number of third conductive vias between another two adjacent first contacts arranged in the first direction among the plurality of first contacts is one. In some embodiments, the at least one second conductive line includes two second conductive lines arranged along a second direction parallel to an extension direction of the plurality of dummy gate replacement patterns, and in the top view, the at least one first conductive line is located between the two second conductive lines, and the at least one third conductive line includes two third conductive lines arranged along the second direction, and in the top view, the at least one first conductive line is located between the two third conductive lines. In some embodiments, in the top view, one of the plurality of first contacts and one of the plurality of second contacts are arranged along the second direction. In some embodiments, the at least one first conductive line includes two first conductive lines arranged along a second direction parallel to an extension direction of the plurality of dummy gate replacement patterns, and in the top view, the at least one second conductive line and the at least one third conductive line are located between the two first conductive lines. In some embodiments, one of the plurality of second conductive vias overlaps two of the plurality of third conductive vias. In some embodiments, another one of the plurality of second conductive vias overlaps one of the plurality of third conductive vias. In some embodiments, in the top view, the plurality of first contacts and the plurality of second contacts are alternately arranged along the first direction, and one of the plurality of first contacts and one of the plurality of second contacts are arranged along the second direction.

According to some embodiments, a semiconductor structure includes a substrate, a plurality of dummy gate replacement patterns, a plurality of source/drain contacts, a plurality of first conductive vias, at least one first conductive line, a plurality of second conductive vias, at least one second conductive line, a plurality of third conductive vias and at least one third conductive line. The substrate has a first surface and a second surface opposite to the first surface. The plurality of dummy gate replacement patterns is disposed on the first surface. The plurality of source/drain contacts is disposed on the first surface, wherein the plurality of dummy gate replacement patterns and the plurality of source/drain contacts are alternately arranged along a first direction, and the plurality of source/drain contacts include a plurality of first contacts and a plurality of second contacts separated from the plurality of first contacts. The plurality of first conductive vias is disposed on the plurality of first contacts. The at least one first conductive line is disposed on the plurality of first conductive vias, wherein the plurality of first contacts is electrically connected to the at least one first conductive line through the plurality of first conductive vias. The plurality of second conductive vias is disposed on the plurality of second contacts. The at least one second conductive line is disposed on the plurality of second conductive vias, wherein the plurality of second contacts is electrically connected to the at least one second conductive line through the plurality of second conductive vias. The plurality of third conductive vias is disposed in the substrate. The at least one third conductive line is disposed on the second surface and electrically connected to the plurality of third conductive vias. In a top view, the semiconductor structure includes at least one first unit, each of the at least one first unit includes three adjacent dummy gate replacement patterns among the plurality of dummy gate replacement patterns and two adjacent second contacts among the plurality of second contacts, and the three adjacent dummy gate replacement patterns and the two adjacent second contacts are alternately arranged along the first direction. In some embodiments, the at least one first unit is disposed in a peripheral region of the semiconductor structure, in a central region of the semiconductor structure or in both of the peripheral region and the central region. In some embodiments, the at least one first unit is disposed between two corresponding first contacts adjacently disposed along the first direction among the plurality of first contacts. In some embodiments, in the top view, the semiconductor structure further includes at least one second unit, each of the at least one second unit includes two adjacent dummy gate replacement patterns among the plurality of dummy gate replacement patterns and one second contact among the plurality of second contacts, and the second contact is disposed between the two adjacent dummy gate replacement patterns. In some embodiments, in the top view, one of the plurality of first contacts is disposed between the at least one first unit and the at least one second unit.

According to some embodiments, a semiconductor structure includes a substrate, a plurality of dummy gate replacement patterns, a plurality of source/drain contacts, a plurality of first conductive vias, at least one first conductive line, a plurality of second conductive vias, at least one second conductive line, a plurality of third conductive vias and at least one third conductive line. The substrate has a first surface and a second surface opposite to the first surface. The plurality of dummy gate replacement patterns is disposed on the first surface. The plurality of source/drain contacts is disposed on the first surface, wherein the plurality of dummy gate replacement patterns and the plurality of source/drain contacts are alternately arranged along a first direction, and the plurality of source/drain contacts include a plurality of first contacts and a plurality of second contacts separated from the plurality of first contacts. The plurality of first conductive vias is disposed on the plurality of first contacts. The at least one first conductive line is disposed on the plurality of first conductive vias, wherein the plurality of first contacts is electrically connected to the at least one first conductive line through the plurality of first conductive vias. The plurality of second conductive vias is disposed on the plurality of second contacts. The at least one second conductive line is disposed on the plurality of second conductive vias, wherein the plurality of second contacts is electrically connected to the at least one second conductive line through the plurality of second conductive vias. The plurality of third conductive vias is disposed in the substrate. The at least one third conductive line is disposed on the second surface and electrically connected to the plurality of third conductive vias. In a top view, one of the plurality of first contacts and one of the plurality of second contacts are arranged along a second direction parallel to an extension direction of the plurality of dummy gate replacement patterns. In some embodiments, the at least one second conductive line includes two second conductive lines arranged along the second direction, and in the top view, the at least one first conductive line is located between the two second conductive lines, and the at least one third conductive line includes two third conductive lines arranged along the second direction, and in the top view, the at least one first conductive line is located between the two third conductive lines. In some embodiments, in the top view, another one of the plurality of second contacts is disposed between another one of the plurality of first contacts and the one of the plurality of first contacts and between another one of the plurality of first contacts and the one of the plurality of second contacts, the one of the plurality of first contacts is shorter than the another one of the plurality of first contacts, and the one of the plurality of second contacts is shorter than the another one of the plurality of second contacts. In some embodiments, the at least one first conductive line includes two first conductive lines arranged along the second direction, and in the top view, the at least one second conductive line and the at least one third conductive line are located between the two first conductive lines. In some embodiments, in the top view, the plurality of first contacts and the plurality of second contacts are alternately arranged along the first direction. In some embodiments, in the top view, the plurality of first contacts is shorter than the plurality of second contacts.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a substrate having a first surface and a second surface opposite to the first surface;
a plurality of dummy gate replacement patterns disposed on the first surface;
a plurality of source/drain contacts disposed on the first surface, wherein the plurality of dummy gate replacement patterns and the plurality of source/drain contacts are alternately arranged along a first direction, and the plurality of source/drain contacts comprise a plurality of first contacts and a plurality of second contacts separated from the plurality of first contacts;
a plurality of first conductive vias disposed on the plurality of first contacts;
at least one first conductive line disposed on the plurality of first conductive vias, wherein the plurality of first contacts is electrically connected to the at least one first conductive line through the plurality of first conductive vias;
a plurality of second conductive vias disposed on the plurality of second contacts;
at least one second conductive line disposed on the plurality of second conductive vias, wherein the plurality of second contacts is electrically connected to the at least one second conductive line through the plurality of second conductive vias;
a plurality of third conductive vias disposed in the substrate; and
at least one third conductive line disposed on the second surface and electrically connected to the plurality of third conductive vias,
wherein in a top view, a number of dummy gate replacement patterns between two adjacent third conductive vias among the plurality of third conductive vias is one.

2. The semiconductor structure as claimed in claim 1, wherein in a cross-sectional view, a number of third conductive vias between two adjacent first contacts arranged in the first direction among the plurality of first contacts is two.

3. The semiconductor structure as claimed in claim 2, wherein in the cross-sectional view, a number of third conductive vias between another two adjacent first contacts arranged in the first direction among the plurality of first contacts is one.

4. The semiconductor structure as claimed in claim 1, wherein:
the at least one second conductive line comprises two second conductive lines arranged along a second direction parallel to an extension direction of the plurality of dummy gate replacement patterns, and in the top view, the at least one first conductive line is located between the two second conductive lines, and
the at least one third conductive line comprises two third conductive lines arranged along the second direction, and in the top view, the at least one first conductive line is located between the two third conductive lines.

5. The semiconductor structure as claimed in claim 4, wherein in the top view, one of the plurality of first contacts and one of the plurality of second contacts are arranged along the second direction.

6. The semiconductor structure as claimed in claim 1, wherein:
the at least one first conductive line comprises two first conductive lines arranged along a second direction parallel to an extension direction of the plurality of dummy gate replacement patterns, and in the top view, the at least one second conductive line and the at least one third conductive line are located between the two first conductive lines.

7. The semiconductor structure as claimed in claim 6, wherein one of the plurality of second conductive vias overlaps two of the plurality of third conductive vias.

8. The semiconductor structure as claimed in claim 7 wherein another one of the plurality of second conductive vias overlaps one of the plurality of third conductive vias.

9. The semiconductor structure as claimed in claim 6, wherein in the top view, the plurality of first contacts and the plurality of second contacts are alternately arranged along the first direction, and one of the plurality of first contacts and one of the plurality of second contacts are arranged along the second direction.

10. A semiconductor structure, comprising:
a substrate having a first surface and a second surface opposite to the first surface;
a plurality of dummy gate replacement patterns disposed on the first surface;
a plurality of source/drain contacts disposed on the first surface, wherein the plurality of dummy gate replacement patterns and the plurality of source/drain contacts are alternately arranged along a first direction, and the plurality of source/drain contacts comprise a plurality of first contacts and a plurality of second contacts separated from the plurality of first contacts;
a plurality of first conductive vias disposed on the plurality of first contacts;
at least one first conductive line disposed on the plurality of first conductive vias, wherein the plurality of first contacts is electrically connected to the at least one first conductive line through the plurality of first conductive vias;
a plurality of second conductive vias disposed on the plurality of second contacts;
at least one second conductive line disposed on the plurality of second conductive vias, wherein the plurality of second contacts is electrically connected to the at least one second conductive line through the plurality of second conductive vias;
a plurality of third conductive vias disposed in the substrate; and
at least one third conductive line disposed on the second surface and electrically connected to the plurality of third conductive vias,
wherein in a top view, the semiconductor structure comprises at least one first unit, each of the at least one first unit comprises three adjacent dummy gate replacement patterns among the plurality of dummy gate replacement patterns and two adjacent second contacts among the plurality of second contacts, and the three adjacent dummy gate replacement patterns and the two adjacent second contacts are alternately arranged along the first direction.

11. The semiconductor structure as claimed in claim 10, wherein the at least one first unit is disposed in a peripheral region of the semiconductor structure, in a central region of the semiconductor structure or in both of the peripheral region and the central region.

12. The semiconductor structure as claimed in claim 10, wherein the at least one first unit is disposed between two corresponding first contacts adjacently disposed along the first direction among the plurality of first contacts.

13. The semiconductor structure as claimed in claim 10, wherein in the top view, the semiconductor structure further comprises at least one second unit, each of the at least one second unit comprises two adjacent dummy gate replacement patterns among the plurality of dummy gate replacement patterns and one second contact among the plurality of second contacts, and the second contact is disposed between the two adjacent dummy gate replacement patterns.

14. The semiconductor structure as claimed in claim 13, wherein in the top view, one of the plurality of first contacts is disposed between the at least one first unit and the at least one second unit.

15. A semiconductor structure, comprising:
a substrate having a first surface and a second surface opposite to the first surface;
a plurality of dummy gate replacement patterns disposed on the first surface;
a plurality of source/drain contacts disposed on the first surface, wherein the plurality of dummy gate replacement patterns and the plurality of source/drain contacts are alternately arranged along a first direction, and the plurality of source/drain contacts comprise a plurality of first contacts and a plurality of second contacts separated from the plurality of first contacts;
a plurality of first conductive vias disposed on the plurality of first contacts;
at least one first conductive line disposed on the plurality of first conductive vias, wherein the plurality of first contacts is electrically connected to the at least one first conductive line through the plurality of first conductive vias;
a plurality of second conductive vias disposed on the plurality of second contacts;
at least one second conductive line disposed on the plurality of second conductive vias, wherein the plurality of second contacts is electrically connected to the at least one second conductive line through the plurality of second conductive vias;
a plurality of third conductive vias disposed in the substrate; and
at least one third conductive line disposed on the second surface and electrically connected to the plurality of third conductive vias,
wherein in a top view, one of the plurality of first contacts and one of the plurality of second contacts are arranged along a second direction parallel to an extension direction of the plurality of dummy gate replacement patterns.

16. The semiconductor structure as claimed in claim 15, wherein:
the at least one second conductive line comprises two second conductive lines arranged along the second direction, and in the top view, the at least one first conductive line is located between the two second conductive lines, and
the at least one third conductive line comprises two third conductive lines arranged along the second direction, and in the top view, the at least one first conductive line is located between the two third conductive lines.

17. The semiconductor structure as claimed in claim 16, wherein in the top view:
another one of the plurality of second contacts is disposed between another one of the plurality of first contacts and the one of the plurality of first contacts and between another one of the plurality of first contacts and the one of the plurality of second contacts,
the one of the plurality of first contacts is shorter than the another one of the plurality of first contacts, and
the one of the plurality of second contacts is shorter than the another one of the plurality of second contacts.

18. The semiconductor structure as claimed in claim 15, wherein:
the at least one first conductive line comprises two first conductive lines arranged along the second direction, and in the top view, the at least one second conductive line and the at least one third conductive line are located between the two first conductive lines.

19. The semiconductor structure as claimed in claim 18, wherein in the top view, the plurality of first contacts and the plurality of second contacts are alternately arranged along the first direction.

20. The semiconductor structure as claimed in claim 18, wherein in the top view, the plurality of first contacts is shorter than the plurality of second contacts.
